(19) United States
(12) Patent Application Publication
(10) Pub. No.: US 2026/0316348 A1
(43) Pub. Date: Oct. 15, 2026

(54) FILM FORMING APPARATUS, FILM FORMING METHOD, ARTICLE MANUFACTURING METHOD AND NON-TRANSITORY COMPUTER-READABLE STORAGE MEDIUM

(71) Applicant: CANON KABUSHIKI KAISHA, Tokyo (JP)

(72) Inventors: YUUKI AOKI, Tochigi (JP); HIROTOSHI TORII, Kanagawa (JP); OSAMU YASUNOBE, Tochigi (JP)

(21) Appl. No.: 19/636,340

(22) Filed: Apr. 1, 2026

(30) Foreign Application Priority Data
Apr. 11, 2025 (JP) 2025-065778

(51) Int. Cl. B29C 43/58; B29C 43/28

(52) U.S. Cl. CPC B29C 43/58; B29C 43/28; B29C 2043/5866

(57) ABSTRACT

A film forming apparatus that forms a film of a curable composition on a substrate by using a mold, the apparatus including a conveyance unit configured to convey the substrate, an observation unit configured to observe a stacked body of the mold and the substrate in a case where the mold cannot be separated from the curable composition on the substrate and the mold is dechucked from a chuck, and a control unit configured to decide, based on an observation result of the observation unit, a conveyance condition for conveying the stacked body, and control the conveyance unit in accordance with the conveyance condition.

### BACKGROUND

### Field of the Technology

The present disclosure relates to a film forming apparatus, a film forming method, an article manufacturing method and a non-transitory computer-readable storage medium.

### Description of the Related Art

In recent years, as a technique for manufacturing an article such as a device, an imprint technique for shaping an imprint material on a substrate by using a mold and curing it has received a great deal of attention. In an imprint apparatus using the imprint technique, when separating (releasing) a mold from an imprint material on a substrate, a force of attracting the mold and the substrate to each other (mold release force) is generated. Due to the mold release force, the mold is deformed (distorted) so that the pattern of the imprint material formed on the substrate is deformed. To prevent this, by adjusting the holding force (such as the suction force) for holding the substrate to allow the substrate to be deformed in accordance with the deformation of the mold, the change of the pattern shape of the imprint material on the substrate is reduced.

In the imprint apparatus, when separating the mold from the imprint material on the substrate, if the mold release force is strong, the mold or the substrate may be detached (come off) from the corresponding holding unit, which is an error called dechucking. In this case, as a recovery sequence against dechucking, Japanese Patent Laid-Open No. 2015-115370 proposes a technique of repeatedly performing an operation of separating the mold from the imprint material on the substrate.

However, when dechucking has occurred, even if the recovery sequence is performed, the mold release force may be too strong so the mold cannot be separated from the imprint material on the substrate, that is, dechucking may not be resolved. If dechucking cannot be resolved, the mold and the substrate not separated from each other (a stacked body of the mold and the substrate) need to be collected by a conveyance mechanism such as a conveyance robot included in the imprint apparatus. In this case, it is necessary to consider the possibility of the substrate falling off from the conveyance mechanism due to some influence during collection of the mold and the substrate.

### SUMMARY

The present disclosure provides a technique advantageous in conveying and collecting a stacked body of a mold and a substrate when dechucking has occurred.

According to one aspect of the present disclosure, there is provided a film forming apparatus that forms a film of a curable composition on a substrate by using a mold, the apparatus including a conveyance unit configured to convey the substrate, an observation unit configured to observe a stacked body of the mold and the substrate in a case where the mold cannot be separated from the curable composition on the substrate and the mold is dechucked from a chuck, and a control unit configured to decide, based on an observation result of the observation unit, a conveyance condition for conveying the stacked body, and control the conveyance unit in accordance with the conveyance condition.

Further aspects of the present disclosure will become apparent from the following description of exemplary embodiments with reference to the attached drawings.

### BRIEF DESCRIPTION OF THE DRAWINGS

FIG. 1 is a schematic view illustrating configurations of an imprint apparatus according to an aspect of the present disclosure.

FIG. 2 is a schematic view illustrating configurations of a processing unit and configurations of a conveyance unit.

FIGS. 3A and 3B are views for describing a mold release step.

FIG. 4 is a flowchart for describing the operation of the imprint apparatus after the mold release step of an imprint process.

FIG. 5 is a view illustrating an example of the positional relationship between a stacked body of the mold and the substrate and the conveyance unit when dechucking has occurred.

FIGS. 6A to 6F are views for describing an article manufacturing method.

FIGS. 7A to 7D are views for describing a case in which the imprint apparatus shown in FIG. 1 is used as a planarization apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

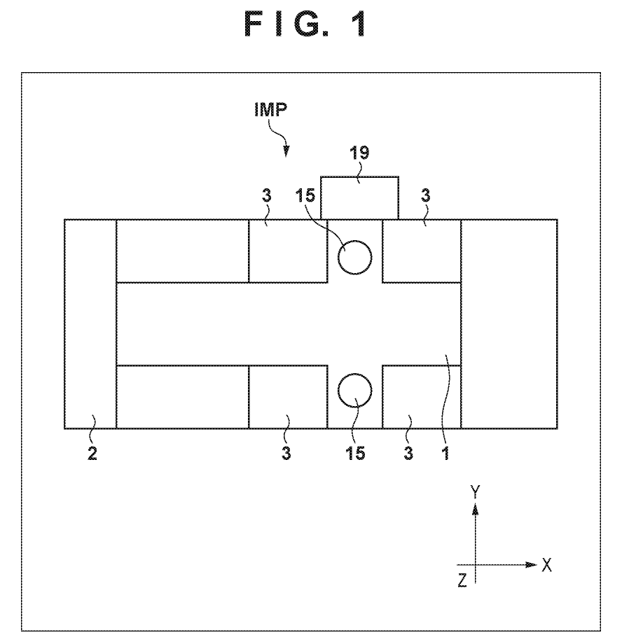

FIG. 1 is a schematic view illustrating configurations of an imprint apparatus IMP according to an aspect of the present disclosure. The imprint apparatus IMP is a film forming apparatus that forms a film of the cured product of a curable composition on a substrate by using a mold. In this embodiment, the imprint apparatus IMP is embodied as a lithography apparatus that is employed in a lithography step, which is a manufacturing step of a device such as a semiconductor device, a liquid crystal display device, or a magnetic storage medium as an article, and forms a pattern on a substrate. The imprint apparatus IMP brings a mold into contact with an imprint material as a curable composition arranged (supplied or applied) on a substrate, and applies curing energy to the imprint material, thereby forming a pattern (film) of a cured product to which the pattern of the mold is transferred.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) are used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25°C) of the imprint material is, for example, 1 mPa∙s (inclusive) to 100 mPa∙s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a plane on which the substrate is placed are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively.

As illustrated in FIG. 1, the imprint apparatus IMP includes a conveyance unit 1, a load/unload unit 2, and a plurality of processing units 3. The conveyance unit 1 conveys a substrate 5 between the load/unload unit 2 and the processing unit 3 and between the plurality of processing units 3. The load/unload unit 2 is a station for loading the substrate 5 to the imprint apparatus IMP and unloading the substrate 5 from the imprint apparatus IMP, and includes, for example, an Equipment Front End Module (EFEM). The processing unit 3 performs an imprint process of shaping the imprint material on the substrate to form a pattern of the imprint material by using a mold 6. Note that in this embodiment, the imprint apparatus IMP includes the plurality of processing units 3, but the imprint apparatus IMP is not limited thereto. The imprint apparatus IMP need only include at least one processing unit 3.

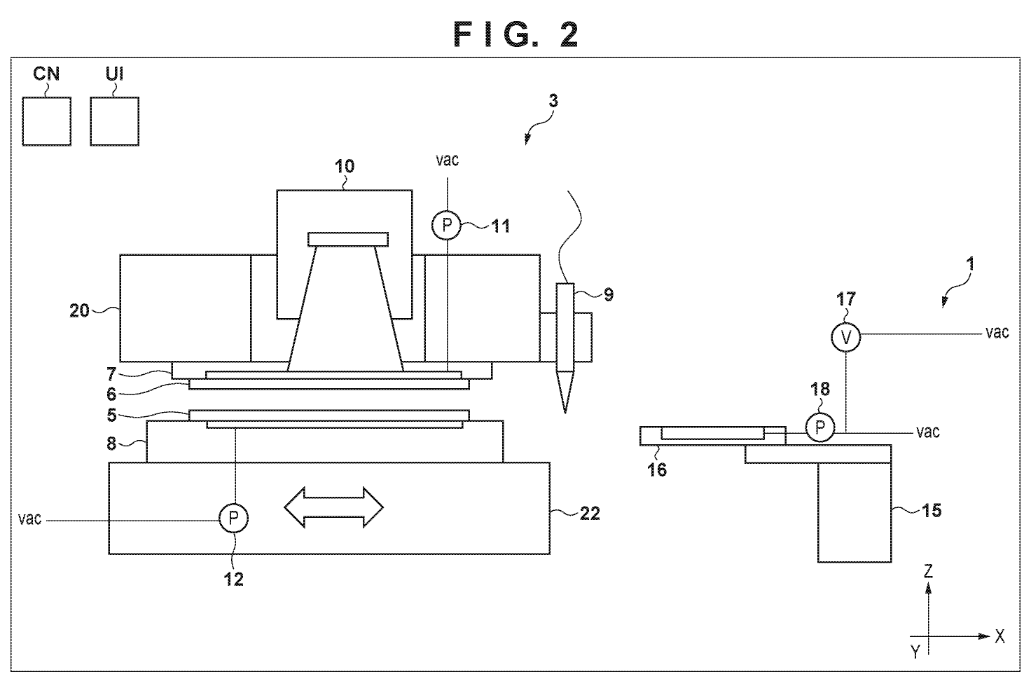

With reference to FIG. 2, configurations of the processing unit 3 and configurations of the conveyance unit 1 will be described more specifically. The conveyance unit 1 includes a hand 16, a moving unit 15, a measurement unit 18, and a change unit 17. The processing unit 3 includes a mold chuck 7, an imprint head 20, a substrate chuck 8, a substrate stage 22, a first measurement unit 9, a spread camera 10, a second measurement unit 11, a third measurement unit 12, and a control unit CN.

The hand 16 holds the substrate 5 to convey the substrate 5. In this embodiment, the hand 16 includes a vacuum pad that attracts the substrate 5 by a vacuum suction force, and holds the substrate 5 via the vacuum pad. However, the hand 16 may include an electrostatic pad that attracts the substrate 5 by an electrostatic force, and hold the substrate 5 via the electrostatic pad. The hand 16 only needs to be capable of applying a holding force to the substrate 5.

The moving unit 15 freely moves the hand 16. The moving unit 15 includes an XYZ driving mechanism for moving (driving) the hand 16 in the X direction, the Y direction, and the Z direction, and a rotation mechanism for rotating the hand 16 about the X-axis, the Y-axis, and the Z-axis.

The measurement unit 18 measures the holding force of the hand 16 for the substrate 5. In this embodiment, the hand 16 includes the vacuum pad. Therefore, the measurement unit 18 includes a pressure sensor arranged in a vacuum line connected to the hand 16 (vacuum pad), and measures the pressure (suction pressure) in the vacuum line as the holding force of the hand 16 for the substrate 5.

The change unit 17 changes the holding force of the hand 16 for the substrate 5. In this embodiment, the hand 16 includes the vacuum pad. Therefore, the change unit 17 is embodied as a switch valve arranged in the vacuum line connected to the hand 16 (vacuum pad). The change unit 17 switches opening/closing (the degree of opening) of the vacuum line, thereby changing the pressure in the vacuum line, that is, the suction force (holding force).

The mold chuck 7 is a mold holding unit that holds the mold 6 on which the pattern to be transferred to the imprint material on the substrate is formed. In this embodiment, the mold chuck 7 is embodied as a vacuum chuck that holds the mold 6 by attracting the outer peripheral region of the mold 6 by a vacuum suction force. However, the mold chuck 7 may be an electrostatic chuck that holds the mold 6 by attracting the outer peripheral region of the mold 6 by an electrostatic force. The mold chuck 7 need only be a chuck that can apply a holding force to the mold 6.

The imprint head 20 includes a Z driving mechanism that supports the mold chuck 7 and moves (drives) the mold chuck 7 (the mold 6 held thereby) in the Z direction. The imprint head 20 may also include a tilt correction mechanism that tilts the mold chuck 7.

The substrate chuck 8 is a substrate holding unit that holds the substrate 5, on which an imprint material serving as the transfer target of the pattern of the mold 6 is arranged. In this embodiment, the substrate chuck 8 is embodied as a vacuum chuck that holds the substrate 5 by attracting the back surface of the substrate 5 by a vacuum suction force. However, the substrate chuck 8 may be an electrostatic chuck that holds the substrate 5 by attracting the back surface of the substrate 5 by an electrostatic force. The substrate chuck 8 need only be a chuck that can apply a holding force to the substrate 5.

The substrate stage 22 includes an XY driving mechanism for supporting the substrate chuck 8 and moves (drives) the substrate chuck 8 (the substrate 5 held thereby) in the X direction and the Y direction. The substrate stage 22 may also include a rotation mechanism for rotating the substrate chuck 8 about the X-axis, the Y-axis, and the Z-axis.

The first measurement unit 9 is provided around the mold chuck 7, for example, on the imprint head 20, and has a function of measuring the substrate 5 held by the substrate chuck 8. The first measurement unit 9 includes, for example, a measuring device (distance sensor) that measures the Z-direction distance from the first measurement unit 9 to the substrate 5 held by the substrate chuck 8, an interferometer (displacement sensor) that measures the Z-direction displacement of the substrate 5 in a non-contact manner, and the like. The first measurement unit 9 measures the substrate 5 held by the substrate chuck 8, and obtains height position information concerning the position of the substrate 5 in the height direction (the position in the Z direction).

The spread camera 10 is arranged above the mold chuck 7, and includes, for example, an illumination system, an optical system, and an image capturing element. The spread camera 10 captures at least one of the mold 6 held by the mold chuck 7 and the substrate 5 held by the substrate chuck 8, thereby obtaining an image. In this embodiment, the spread camera 10 obtains an image including the state of the imprint material as it spreads when the mold 6 and the imprint material on the substrate come into contact with each other, and an image including the bonding state (contact state) between the mold 6 and the substrate 5 via the imprint material on the substrate.

The second measurement unit 11 measures the holding force of the mold chuck 7 for the mold 6. In this embodiment, the mold chuck 7 is a vacuum chuck. Therefore, the second measurement unit 11 includes a pressure sensor arranged in the vacuum line connected to the mold chuck 7, and measures the pressure in the vacuum line (the suction pressure of the mold chuck 7) as the holding force of the mold chuck 7 for the mold 6.

The third measurement unit 12 measures the holding force of the substrate chuck 8 for the substrate 5. In this embodiment, the substrate chuck 8 is a vacuum chuck. Therefore, the third measurement unit 12 includes a pressure sensor arranged in the vacuum line connected to the substrate chuck 8, and measures the pressure in the vacuum line (the suction pressure of the substrate chuck 8) as the holding force of the substrate chuck 8 for the substrate 5.

The control unit CN is formed by an information processing apparatus (computer) including a CPU, a memory, and the like. The control unit CN operates the imprint apparatus IMP by comprehensively controlling the respective units of the imprint apparatus IMP in accordance with the program stored in a storage unit. The control unit CN controls the imprint process of forming a pattern in the imprint material by transferring the pattern of the mold 6 to the imprint material on the substrate, and various kinds of processes associated with the imprint process.

Each step of the imprint process in the imprint apparatus IMP will be described. The imprint process includes an arranging step, a contact step, a curing step, and a mold release step. The arranging step is a step of arranging an imprint material on a substrate. The contact step is a step of bringing the imprint material on the substrate into contact with the mold 6. The curing step is a step of curing the imprint material in a state in which the imprint material on the substrate is in contact with the mold 6. The mold release step is a step of separating the mold 6 from the cured imprint material on the substrate.

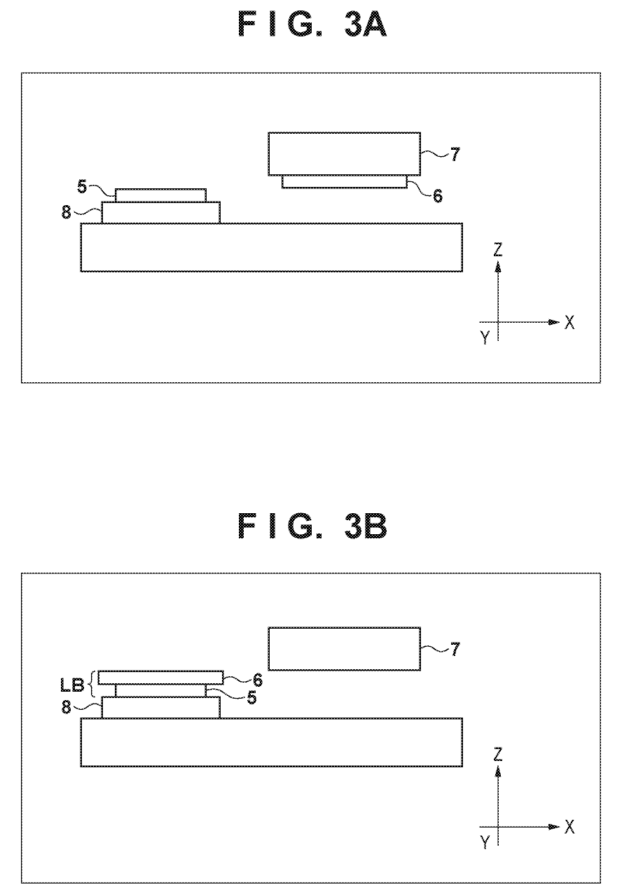

Here, focusing on the mold release step, when separating the mold 6 from the imprint material on the substrate, a mold release force (a force attracting the mold 6 and the substrate 5 each other) is generated. Therefore, as shown in FIGS. 3A and 3B, the mold release step is not always performed successfully. FIG. 3A illustrates a state in which the mold release step is performed successfully. The mold 6 is separated from the substrate 5, and dechucking, in which the mold 6 and the substrate 5 are detached from the mold chuck 7 and the substrate chuck 8, respectively, has not occurred. On the other hand, FIG. 3B illustrates a state in which an abnormality has occurred in the mold release step. The mold 6 is not separated from the substrate 5, and dechucking has occurred, in which the mold 6 is detached from the mold chuck 7. The mold 6 and the substrate 5 not separated from each other in this manner will be referred to as a stacked body LB of the mold 6 and the substrate 5, or simply the stacked body LB.

If dechucking has occurred in the mold release step, a recovery sequence is performed in which an operation of separating the mold 6 from the imprint material on the substrate is repeatedly performed. However, dechucking may not be resolved even if the recovery sequence is performed. In this case, in order to suppress the decline in the operating rate of the imprint apparatus IMP, the stacked body LB of the mold 6 and the substrate 5 needs to be rapidly conveyed from the processing unit 3 to the load/unload unit 2 to collect it.

Therefore, in this embodiment, if dechucking has occurred, the conveyance unit 1 included in the imprint apparatus IMP is used to convey the stacked body LB of the mold 6 and the substrate 5 from the processing unit 3 to the load/unload unit 2 and collect it. However, the conveyance unit 1 is basically configured for the conveyance of only the substrate 5, and is not configured for the conveyance of the stacked body LB of the mold 6 and the substrate 5. Hence, when using the conveyance unit 1, a technique is required for conveying the stacked body LB without causing physical interference of the stacked body LB and falling the stacked body LB (or the mold 6) in the step of conveying and collecting the stacked body LB. In this embodiment, a technique for safely conveying and collecting the stacked body LB of the mold 6 and the substrate 5 by using the conveyance unit 1, that is, a technique advantageous in conveying and collecting the stacked body LB is provided.

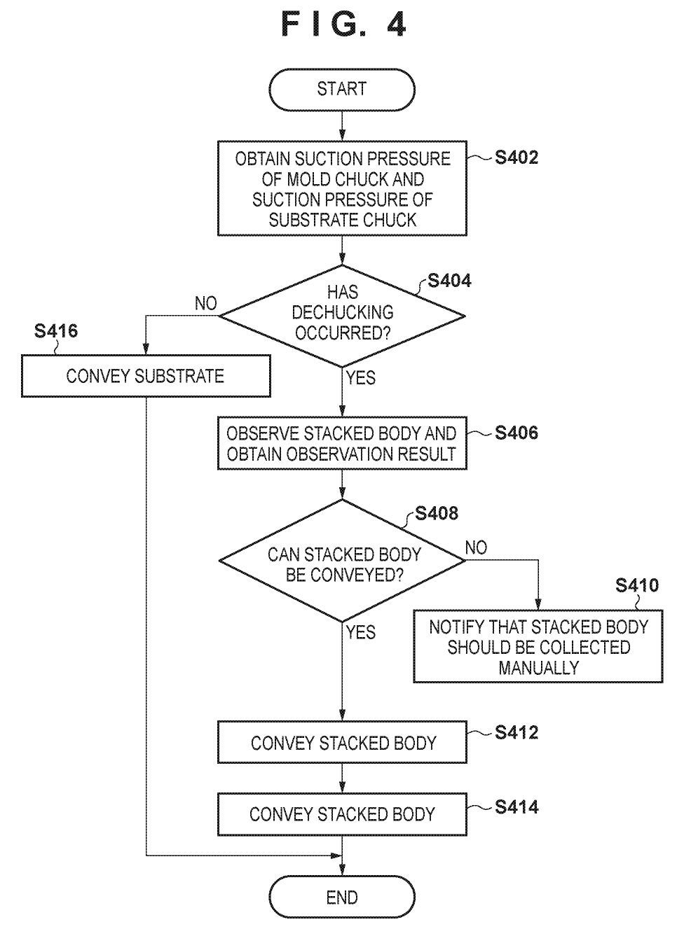

In this embodiment, with reference to FIG. 4, the operation of the imprint apparatus IMP after the mold release step of the imprint process will be described below. As described above, this operation is performed by the control unit CN collectively controlling the respective units of the imprint apparatus IMP. Note that a description of the recovery sequence, which is performed when dechucking has occurred, will be omitted.

In step S402, the suction pressure of the mold chuck 7, which corresponds to the holding force of the mold chuck 7 for the mold 6, and the suction pressure of the substrate chuck 8, which corresponds to the holding force of the substrate chuck 8 for the substrate 5, are obtained from the second measurement unit 11 and the third measurement unit 12, respectively.

In step S404, based on the suction pressure of the mold chuck 7 and the suction pressure of the substrate chuck 8 obtained in step S402, it is determined whether dechucking, in which the mold 6 is detached from the mold chuck 7, has occurred. More specifically, each of the suction pressure of the mold chuck 7 and the suction pressure of the substrate chuck 8 is compared with a predetermined value (for example, -50 Pa). If the suction pressure of the mold chuck 7 exceeds the predetermined value and the suction pressure of the substrate chuck 8 does not exceed the predetermined value, it is determined that dechucking has occurred (occurrence of dechucking is detected). If dechucking has occurred, the process transitions to step S406. On the other hand, if no dechucking has occurred, the process transitions to step S416.

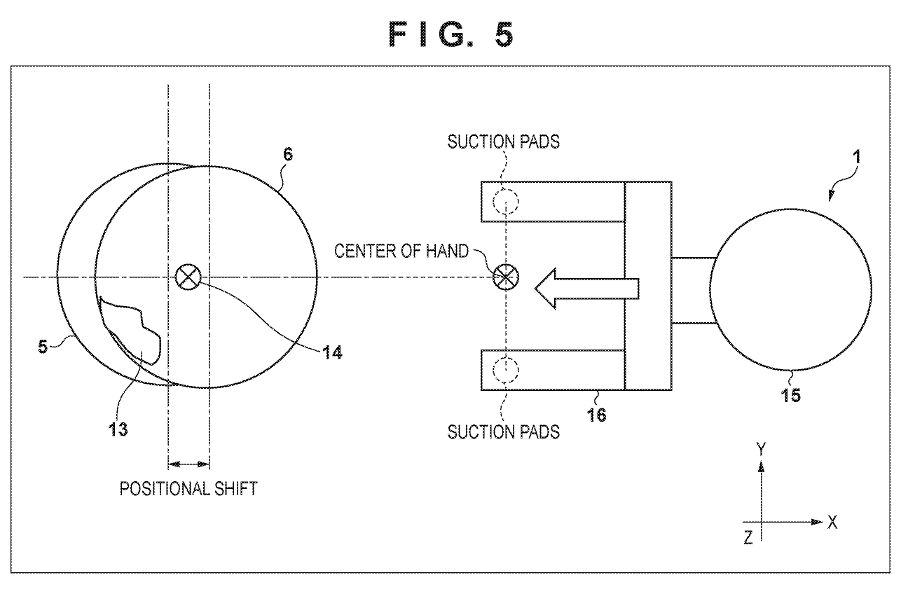

In step S406, the stacked body LB of the mold 6 and the substrate 5 is observed, and an observation result is obtained. The stacked body LB is observed using the first measurement unit 9 and the spread camera 10. For example, while moving (scanning) the substrate chuck 8 in the X direction and the Y direction below the first measurement unit 9, the first measurement unit 9 measures the stacked body LB held by the substrate chuck 8. With this, the position of the stacked body LB in the height direction (the three-dimensional shape of the stacked body LB (the bulging state (unevenness or step) of the stacked body LB in the height direction)), the positional shift between the mold 6 and the substrate 5 in the stacked body LB, and a barycenter 14 (the position thereof) of the stacked body LB can be obtained. In addition, the spread camera 10 arranged above the mold chuck 7 captures the stacked body LB held by the substrate chuck 8, thereby obtaining an image. With this, in addition to the positional shift between the mold 6 and the substrate 5 in the stacked body LB and the barycenter 14 of the stacked body LB, an air trap 13 present between the mold 6 and the substrate 5 in the stacked body LB is obtained, as shown in FIG. 5. Note that the air trap 13 is a region where no imprint material exists between the mold 6 and the substrate 5, that is, a space, so that this can cause the mold 6 to easily peel and fall off from the substrate 5. In this manner, in this embodiment, the first measurement unit 9 and the spread camera 10 function as an observation unit that observes the stacked body of the mold 6 and the substrate 5 in a case where the mold 6 cannot be separated from the imprint material on the substrate and the mold 6 is dechucked from the mold chuck 7. As the observation result of the observation unit, at least one of the position of the stacked body LB in the height direction, the air trap 13 present between the mold 6 and the substrate 5 in the stacked body LB, the positional shift between the mold 6 and the substrate 5 in the stacked body LB, and the position of the barycenter 14 of the stacked body LB is obtained.

In step S408, from the observation result obtained in step S406, it is determined whether conveyance of the stacked body LB by the conveyance unit 1 is possible, that is, whether the conveyance unit 1 can convey the stacked body LB.

For example, from the observation result obtained in step S406, the position of the stacked body LB in the height direction, the positional shift between the mold 6 and the substrate 5 in the stacked body LB, and the position of the barycenter 14 of the stacked body LB are compared with the size of a conveyance path from the processing unit 3 to the load/unload unit 2. As a result, if there is no physical interference of the stacked body LB in the conveyance path from the processing unit 3 to the load/unload unit 2, it is determined that the conveyance unit 1 can convey the stacked body LB. Note that the size of the conveyance path from the processing unit 3 to the load/unload unit 2 can be obtained from the design information of the conveyance unit 1 and the conveyance path, and can be set in the imprint apparatus IMP (the storage unit thereof) in advance.

From the observation result obtained in step S406, the position and proportion of the air trap 13 are analyzed. If the possibility of the mold 6 falling off from the substrate 5 is low, it is determined that the conveyance unit 1 can convey the stacked body LB. For example, if the position of the air trap 13 is not in the peripheral region of the stacked body LB, or if the proportion of the air trap 13 is 20% or less, it is considered that the possibility of the mold 6 falling off from the substrate 5 is low.

Similar to the air trap 13, from the observation result obtained in step S406, the positional shift between the mold 6 and the substrate 5 in the stacked body LB and the position of the barycenter 14 of the stacked body LB can be analyzed. If the possibility of the mold 6 falling off from the substrate 5 is low, it is determined that the conveyance unit 1 can convey the stacked body LB.

In this manner, it is determined whether conveyance of the stacked body LB by the conveyance unit 1 is possible. If conveyance of the stacked body LB is possible, the process transitions to step S412. If conveyance of the stacked body LB is not possible, the process transitions to step S410.

In step S410, via a user interface UI included in the imprint apparatus IMP, it is notified that conveyance of the stacked body LB by the conveyance unit 1 is not possible so that the stacked body LB of the mold 6 and the substrate 5 held by the substrate chuck 8 should be collected manually. The user interface UI is a unit that includes, for example, a display apparatus, a sound output apparatus, or the like, and is used to notify the user of various kinds of information regarding the imprint apparatus IMP. In step S410, the stacked body LB is not conveyed by the conveyance unit 1, but the user opens a temporary collection door 19 provided in the imprint apparatus IMP and manually collects the stacked body LB held by the substrate chuck 8. Note that if a conveyance path from the processing unit 3 to the temporary collection door 19 (the vicinity thereof) is ensured, the stacked body LB may be conveyed by the conveyance unit 1 from the processing unit 3 to the temporary collection door 19. Note that, in this case, it must be ensured that no physical interference of the stacked body LB occurs and the mold 6 does not fall off from substrate 5 in the conveyance path from the processing unit 3 to the temporary collection door 19 (the vicinity thereof). A movable load port may be provided, as needed.

In step S412, based on the observation result obtained in step S406, the conveyance condition of the conveyance unit 1 for conveying the stacked body LB of the mold 6 and the substrate 5 from the processing unit 3 to the load/unload unit 2 is decided.

The conveyance condition of the conveyance unit 1 is, for example, a holding position for holding the stacked body LB by the hand 16. Here, the holding position means the position where the hand 16 holds the stacked body LB in the X and Y directions. In this case, based on the observation result obtained in step S406, the holding position by the hand 16 is decided so that physical interference of the stacked body LB held by the hand 16 is avoided in the conveyance path of the stacked body LB by the conveyance unit 1 (the conveyance path from the processing unit 3 to the load/unload unit 2). Basically, as shown in FIG. 5, it is preferable to decide the holding position by the hand 16 so that the position of the center of the hand 16 (suction pads) matches the position of the barycenter 14 of the stacked body LB.

The conveyance condition of the conveyance unit 1 is, for example, at least one of the speed and acceleration of the moving unit 15 for moving the hand 16 holding the stacked body LB. In this case, based on the observation result obtained in step S406, at least one of the speed and acceleration of the moving unit 15 for moving the hand 16 is decided so that the vibration of the stacked body LB held by the hand 16 falls within an allowable range. The allowable range of the vibration of the stacked body LB held by the hand 16 is set to a range where it is ensured that the stacked body LB does not fall off from the substrate chuck 8 and that the mold 6 does not fall off from the substrate 5. Note that, in addition to the observation result obtained in step S406, the weight of the stacked body LB (the total weight of the weight of the mold 6 and the weight of the substrate 5) may be considered to decide at least one of the speed and acceleration of the moving unit 15 for moving the hand 16.

The conveyance condition of the conveyance unit 1 is, for example, the position of the hand 16 in the height direction while the hand 16 holding the stacked body LB is moved by the moving unit 15. In this case, based on the observation result obtained in step S406, the position of the hand 16 in the height direction is decided so that physical interference of the stacked body LB held by the hand 16 is avoided in the conveyance path of the stacked body LB by the conveyance unit 1. Note that, in addition to the observation result obtained in step S406, the bending amount of the hand 16 due to the weight of the stacked body LB may be considered to decide the position of the hand 16 in the height direction.

The conveyance condition of the conveyance unit 1 is, for example, the holding force of the hand 16, which is the suction force of the hand 16 in this embodiment, for the stacked body LB while the hand 16 holding the stacked body LB is moved by the moving unit 15. In this case, based on the observation result obtained in step S406, the suction force of the hand 16 is decided so that falling of the stacked body LB held by the hand 16 is avoided. For example, if the holding force of the hand 16 is insufficient, the suction force of the hand 16 is increased via the change unit 17 (switch valve). At this time, at least one of the speed and acceleration of the moving unit 15 for moving the hand 16 may be decreased. Note that, in addition to the observation result obtained in step S406, the weight of the stacked body LB may be considered to decide the suction force of the hand 16.

If there are a plurality of conveyance paths for conveying the stacked body LB, the conveyance condition of the conveyance unit 1 may be the conveyance path. In this case, based on the observation result obtained in step S406, the conveyance path where the stacked body LB can be conveyed without physical interference of the stacked body LB held by the hand 16 is decided from the plurality of conveyance paths for conveying the stacked body LB.

In step S414, the conveyance unit 1 is controlled in accordance with the conveyance condition decided in step S412, thereby conveying the stacked body LB from the processing unit 3 to the load/unload unit 2.

In step S416, since no dechucking has occurred, the conveyance unit 1 is controlled in accordance with the conveyance condition set in default (the conveyance condition of the conveyance unit 1 for conveying the substrate 5), thereby conveying the substrate 5 from the processing unit 3 to the load/unload unit 2.

As described above, according to this embodiment, if dechucking has occurred, it is possible to convey the stacked body LB by using the conveyance unit 1 without causing physical interference of the stacked body LB and falling the stacked body LB (or the mold 6). Accordingly, a technique for safely conveying and collecting the stacked body LB of the mold 6 and the substrate 5, that is, a technique advantageous in conveying and collecting the stacked body LB can be provided.

The pattern of a cured product formed using the imprint apparatus IMP in the embodiment is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

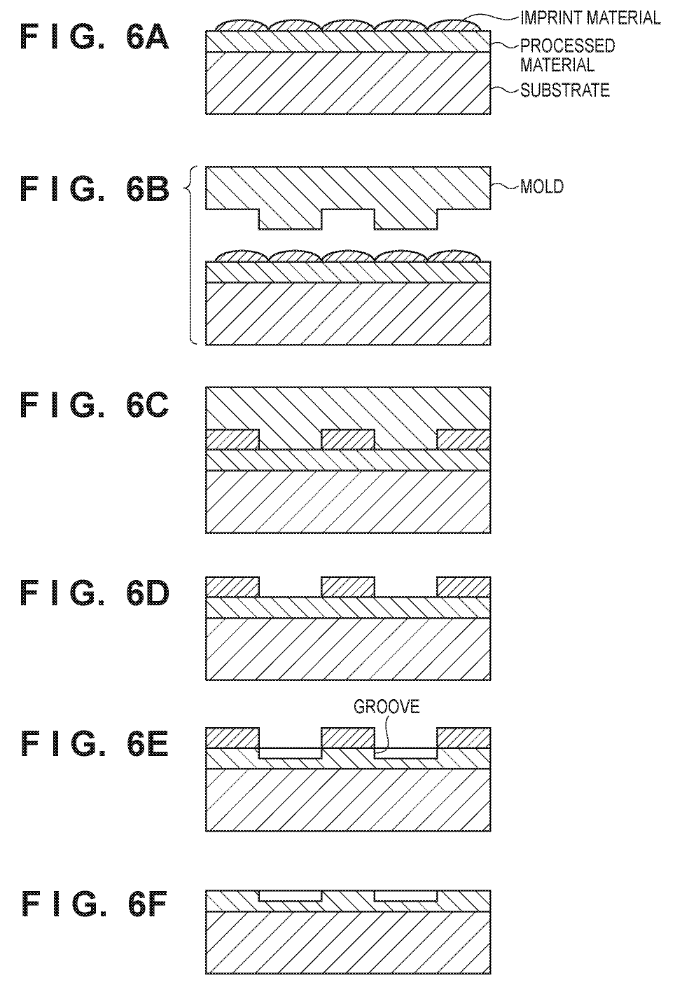

Next, description regarding a detailed method of manufacturing an article is given. As illustrated in FIG. 6A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 6B, a side of the mold for imprint with a projection and groove pattern is formed and caused to face the imprint material on the substrate. As illustrated in FIG. 6C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 6D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 6E, when etching is performed using the pattern of the cured product as an etching resistant mask, a portion of the surface of the processed material where the cured product does not exist or remains thin is removed to form a groove. As shown in FIG. 6F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

As the mold 6, a circuit pattern transfer mold with a pattern formed thereon has been described above. However, the mold 6 may be a mold (plane template) having a flat surface without a pattern formed thereon. The plane template is used in a planarization apparatus that performs a planarization process of performing shaping such that a curable composition on a substrate is planarized by the flat surface. The planarization process includes a step of curing the curable composition by light irradiation or heating in a state in which the flat surface of the plane template is in contact with the curable composition supplied onto the substrate.

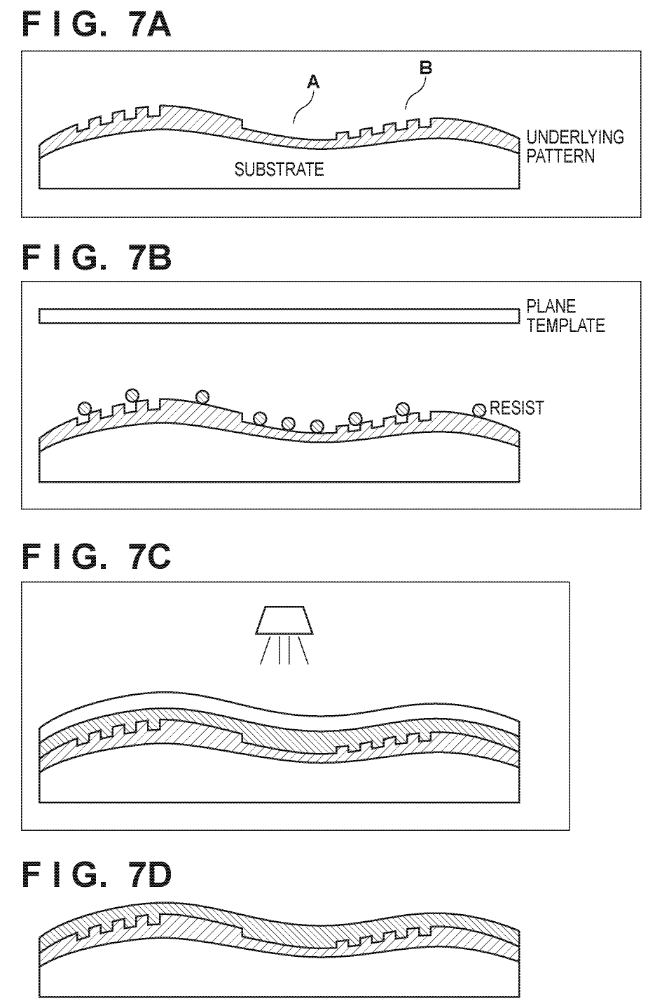

The underlying pattern on the substrate has an uneven profile derived from the pattern formed in the previous step. In particular, with the recent multilayered structure of a memory element, the substrate (process wafer) may have a step of about 100 nm. The step derived from a moderate undulation of the entire substrate can be corrected by the focus following function of an exposure apparatus (scanner) used in the photolithography step. However, an unevenness with a small pitch fitted in the exposure slit area of the exposure apparatus directly consumes the DOF (Depth Of Focus) of the exposure apparatus. As a conventional technique of planarizing the underlying pattern of a substrate, a technique of forming a planarization layer, such as SOC (Spin On Carbon) or CMP (Chemical Mechanical Polishing), is used. In the conventional technique, however, as shown in FIG. 7A, an unevenness suppressing rate of only 40% to 70% is obtained in the boundary portion between an isolated pattern region A and a repetitive dense (concentration of a line & space pattern) pattern region B, and sufficient planarization performance cannot be obtained. The unevenness difference of the underlying pattern caused by the multilayered structure tends to further increase in the future.

As a solution to this problem, U.S. Patent No. 9,415,418 proposes a technique of forming a continuous film by application of a resist serving as a planarization layer by an inkjet dispenser and pressing by a plane template. Also, U.S. Patent No. 8,394,282 proposes a technique of reflecting a topography measurement result on a substrate side on density information for each position to instruct application by an inkjet dispenser. An imprint apparatus IMP can particularly be applied as a planarization processing (planarization) apparatus for performing local planarization in a substrate surface by pressing not the mold 6 but a plane template against an uncured resist applied in advance.

FIG. 7A shows a substrate before planarization processing. In the isolated pattern region A, the area of a pattern convex portion is small. In the repetitive dense pattern region B, the ratio of the area of a pattern convex portion to the area of a pattern concave portion is 1 : 1. The average height of the isolated pattern region A and the repetitive dense pattern region B changes depending on the ratio of the pattern convex portion.

FIG. 7B shows a state in which the resist that forms the planarization layer is applied to the substrate. FIG. 7B shows a state in which the resist is applied by an inkjet dispenser based on the technique proposed in U.S. Patent No. 9,415,418. However, a spin coater may be used to apply the resist. In other words, the imprint apparatus IMP can be applied if a step of pressing a plane template against an uncured resist applied in advance to planarize the resist is included.

As shown in FIG. 7C, the plane template is made of glass or quartz that passes UV rays, and the resist is cured by irradiation of UV rays from a light source. For the moderate unevenness of the entire substrate, the plane template conforms to the profile of the substrate surface. After the resist is cured, the plane template is separated from the resist, as shown in FIG. 7D.

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)TM), a flash memory device, a memory card, and the like.

According to the present disclosure, for example, it is possible to provide a technique advantageous in conveying and collecting a stacked body of a mold and a substrate when dechucking has occurred.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent application No. 2025-065778 filed on Apr. 11, 2025, which is hereby incorporated by reference herein in its entirety.

What is claimed is:

1. A film forming apparatus that forms a film of a curable composition on a substrate by using a mold, the apparatus comprising:
a conveyance unit configured to convey the substrate;
an observation unit configured to observe a stacked body of the mold and the substrate in a case where the mold cannot be separated from the curable composition on the substrate and the mold is dechucked from a chuck; and
a control unit configured to decide, based on an observation result of the observation unit, a conveyance condition for conveying the stacked body, and control the conveyance unit in accordance with the conveyance condition.

2. The apparatus according to claim 1, wherein
the observation unit observes at least one of a position of the stacked body in a height direction, an air trap present between the mold and the substrate in the stacked body, a positional shift between the mold and the substrate in the stacked body, and a position of a barycenter of the stacked body.

3. The apparatus according to claim 1, wherein
the control unit
determines, based on the observation result, whether conveyance of the stacked body by the conveyance unit is possible,
decides the conveyance condition in a case where conveyance of the stacked body by the conveyance unit is possible, and
notifies that the stacked body is to be collected manually without deciding the conveyance condition in a case where conveyance of the stacked body by the conveyance unit is not possible.

4. The apparatus according to claim 1, wherein
the conveyance unit includes a hand configured to hold one of the substrate and the stacked body, and a moving unit configured to move the hand,
the conveyance condition includes a holding position for holding the stacked body by the hand, and
the control unit decides, based on the observation result, the holding position so that physical interference of the stacked body held by the hand is avoided in a conveyance path of the stacked body by the conveyance unit.

5. The apparatus according to claim 1, wherein
the conveyance unit includes a hand configured to hold one of the substrate and the stacked body, and a moving unit configured to move the hand,
the conveyance condition includes at least one of speed and acceleration of the moving unit for moving the hand holding the stacked body, and
the control unit decides, based on the observation result, at least one of the speed and acceleration so that vibration of the stacked body held by the hand falls within an allowable range.

6. The apparatus according to claim 1, wherein
the conveyance unit includes a hand configured to hold one of the substrate and the stacked body, and a moving unit configured to move the hand,
the conveyance condition includes a position of the hand in a height direction while the hand holding the stacked body is moved by the moving unit, and
the control unit decides, based on the observation result, a position of the hand in a height direction so that physical interference of the stacked body held by the hand is avoided in a conveyance path of the stacked body by the conveyance unit.

7. The apparatus according to claim 1, wherein
the conveyance unit includes a hand configured to hold one of the substrate and the stacked body, and a moving unit configured to move the hand,
the conveyance condition includes a holding force of the hand for the stacked body while the hand holding the stacked body is moved by the moving unit, and
the control unit decides, based on the observation result, a holding force of the hand so that falling of the stacked body held by the hand is avoided.

8. The apparatus according to claim 1, wherein
the conveyance unit includes a plurality of conveyance paths for conveying the stacked body, and
based on the observation result, the control unit decides, from the plurality of conveyance paths, a conveyance path where the stacked body can be conveyed as the conveyance condition.

9. The apparatus according to claim 1, further comprising a measurement unit configured to measure a holding force of the chuck for the mold,
wherein, in a case where the holding force measured by the measurement unit exceeds a predetermined value, the control unit detects that the mold is dechucked from the chuck.

10. The apparatus according to claim 1, wherein
the mold includes a pattern, and
the film has a pattern corresponding to the pattern of the mold.

11. The apparatus according to claim 1, wherein
the mold includes a flat surface, and
the film has a surface conforming to the flat surface of the mold.

12. A film forming method of forming a film of a curable composition on a substrate by using a mold, the method comprising:
observing a stacked body of the mold and the substrate in a case where the mold cannot be separated from the curable composition on the substrate and the mold is dechucked from a chuck; and
deciding, based on an observation result in the observing, a conveyance condition for conveying the stacked body by a conveyance unit configured to convey the substrate, and controlling the conveyance unit in accordance with the conveyance condition.

13. An article manufacturing method comprising:
forming a film of a curable composition on a substrate using a film forming apparatus defined in claim 1;
processing the substrate on which the film is formed; and
manufacturing an article from the processed substrate.

14. A non-transitory computer-readable storage medium storing a program configured to cause a computer to execute each step of a film forming method defined in claim 12.
